(19) United States
(12) Patent Application Publication
(10) Pub. No.: US 2004/0231716 A1
(43) Pub. Date: Nov. 25, 2004

(54) Wireless controlled battery powered heliostats for solar power plant application

(76) Inventor: Robert Zachary Litwin, Canoga Park, CA (US)

Correspondence Address: HARNESS, DICKEY & PIERCE, P.L.C., P.O. BOX 828, BLOOMFIELD HILLS, MI, 48303, US

(21) Appl. No.: 10/443,561

(22) Filed: May 22, 2003

(51) Int. Cl. H01L 31/00

(52) U.S. Cl. 136/246; 136/244; 136/291

(57) ABSTRACT

A remotely powered heliostat system includes a plurality of heliostats each having a reflection panel movably disposed on a structural member. At least one motor is disposed between each heliostat and the structural member to position each heliostat. The plurality of heliostats is further divisible into at least two groups of heliostats, each group operable by one of a plurality of radio frequency receivers electrically connected to each motor. Each radio frequency receiver wirelessly receives a heliostat positioning command for the group from a remote transmitter. A processor analyzes solar position and generates the heliostat positioning command. Encoders on each heliostat keep track of the heliostat position. Each motor is connected to a local battery unit to provide electrical power. The system provides local power to operate each heliostat, and a wireless signal to control heliostat position, eliminating dependence on a single source of power for the heliostats.

### FIELD OF THE INVENTION

The present invention relates generally to heliostats and more specifically to an apparatus and a method to control the operation of one or more heliostats.

### BACKGROUND OF THE INVENTION

Heliostats are partially formed of reflective surfaces called facets and are commonly used to collect solar radiation and reflect the solar radiation onto a solar receiver mounted on a tall tower. Heliostat facets are typically arranged such that an individual facet or several facets form a heliostat reflector. A heliostat is formed with at least one reflector supported from a support structure, having at least one motor disposed between the support structure and reflector to position the reflector relative to a solar position. Additional components can also be included with each heliostat. When thousands of heliostats are used to form heliostat fields, solar electrical power can be generated comparable to fossil fuel or nuclear electric generation plants. Heliostat fields are also used in scientific research, to collect/reflect energy from cosmic sources.

Several disadvantages exist for known heliostats. Large quantities or fields of heliostats require individual cabling between the necessary control facility and each heliostat, often totaling kilometers of cabling for a several thousand heliostat field. Both power and control signal cabling are required. These cables are often buried and difficult to access for maintenance. Initial installation cost as well as maintenance costs are therefore increased by the total amount of cabling. Power and operational signals for each heliostat are commonly provided from a control facility remotely located from the heliostat field. Even a temporary power outage at the control facility can render the entire heliostat field inoperative. The loss of power to an entire field or sector of heliostats can result in a serious thermal threat to the receiver and/or tower as the combined heliostat thermal flux “walks off” the receiver surface and/or impinges on tower structural materials. Even momentary power loss can result in thermal damage to the receiver and/or tower. Back-up electrical sources are therefore often provided in the event of a general power failure, further increasing cost. Heliostats are also susceptible to high wind or weather damage, therefore requiring re-positioning to a safe position during inclement weather. A prolonged loss of electrical power can therefore result in heliostat weather related damage.

It is therefore desirable to provide a heliostat system capable of powering each heliostat or group of heliostats, independent of each other and independent of the power source required to generate the control signals. It is also desirable to eliminate the individual power and control cabling required between the control facility and each heliostat.

### SUMMARY OF THE INVENTION

A locally powered heliostat system includes a plurality of heliostats each having at least one facet operably forming a reflector, the reflector movably disposed on a structural member. At least one motor is disposed between each reflector and the structural member to position each reflector. The plurality of heliostats is further divisible into at least two groups of heliostats, each group operable by one of a plurality of radio frequency receivers electrically connected to each motor (or group of motors). Each radio frequency receiver wirelessly receives a heliostat positioning command for the group from a remote transmitter.

In one preferred embodiment, a processor which is remotely located from a field of heliostats analyzes a solar position and generates heliostat positioning commands. The heliostat positioning commands are transferred to a radio frequency transmitter. A radio frequency, wireless signal is generated by the transmitter and transmitted to each heliostat to control heliostat position. The receiver located at each heliostat receives the wirelessly transmitted control signal where it is further communicated to each motor. In the event of a loss of control signals from the transmitter, each heliostat or group of heliostats can be directed to a fail-safe position stored in the receiver of each heliostat, or retained in the existing position.

In another preferred embodiment, each motor is connected to at least one local battery unit to provide electrical power to position the heliostat. The battery unit provides direct current power independent of the power required to operate the processor and transmitter. A photovoltaic cell array is disposed at each heliostat or group of heliostats which generates electrical current to recharge the battery unit. Power conditioning equipment and battery monitoring equipment are also provided to control the recharge process and to monitor battery unit condition, respectively.

In yet another preferred embodiment, the processor is mounted on the heliostat. In this embodiment, the battery unit also provides direct current power to the processor.

In still another preferred embodiment, a unique address on a radio frequency signal is generated for each individual heliostat. By controlling each individual heliostat using a unique address signal, individual heliostats or groups of heliostats can be positioned from a remote control facility.

Further areas of applicability of the present invention will become apparent from the detailed description provided hereinafter. It should be understood that the detailed description and specific examples are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 is a diagrammatic view of a heliostat system according to a preferred embodiment of the present invention;

FIG. 2 is a diagrammatic view of the heliostat system according to another embodiment of the present invention, showing individual groups of heliostats in communication with a receiver and tower known in the art;

FIG. 3 is a flow chart identifying a method to operate a heliostat system of the present invention; and

FIG. 4 is a perspective view of an exemplary heliostat of the present invention.

### DETAILED DESCRIPTION OF THE PREFERRED EMBODIMENTS

The following description of the preferred embodiments is merely exemplary in nature and is in no way intended to limit the invention, its application, or uses.

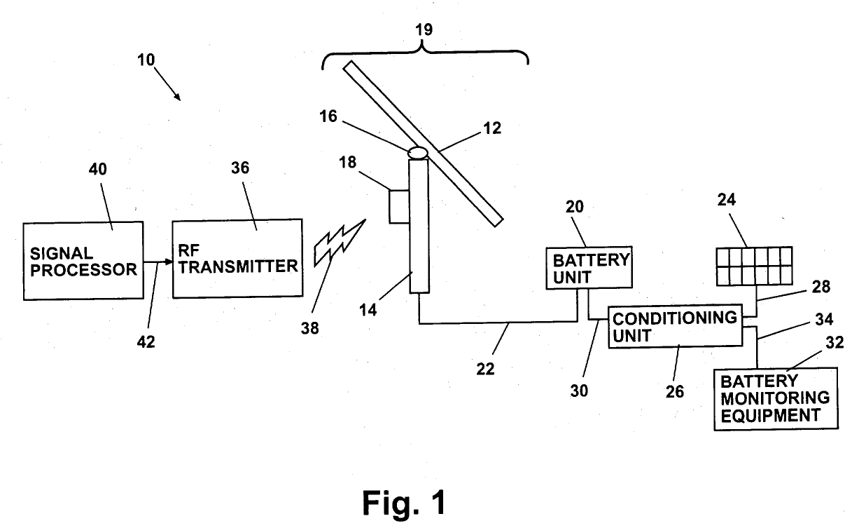

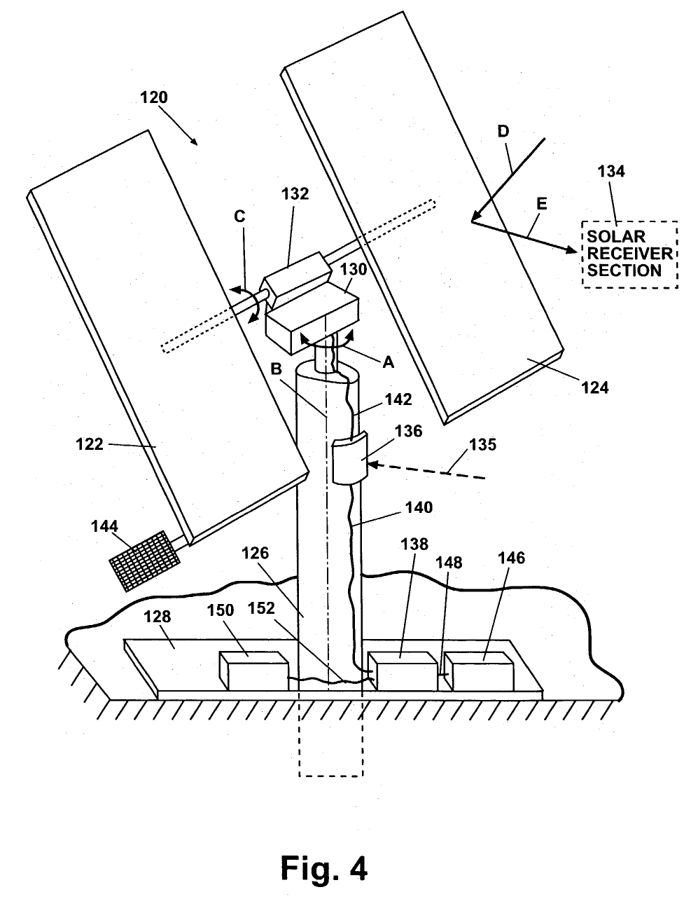

Referring to FIG. 1, a heliostat system 10 of the present invention includes at least one reflector 12 supported by a structural member 14. Each structural member 14 is separately positioned and supported by a ground surface or additional support pad (shown in reference to FIG. 4). At least one motor 16 is disposed between the structural member 14 and each reflector 12. In a preferred embodiment, the motor 16 includes a separate elevation control motor and gear and a separate azimuth control motor and gear (shown in reference to FIG. 4). A radio frequency receiver 18 is also disposed on each structural member 14. At least one each of reflector 12, structural member 14, motor 16 and receiver 18 form an assembly, hereinafter designated as heliostat 19. A plurality of heliostats 19 are grouped to form a heliostat field.

In the embodiment shown, at least one battery unit 20 is disposed either in close proximity to or mounted from each structural member 14. Direct current (DC) power from the battery unit 20 is provided to each of the motors 16 via a motor power line 22. A photovoltaic cell array 24 is also disposed in close proximity to each structural member 14, mounted from each structural member 14, or alternatively, disposed on each of the reflectors 12. The photovoltaic cell array 24 is selected from systems known in the art to provide the necessary voltage and current for recharging the battery unit 20. Each battery unit 20 preferably includes at least one lead-acid battery known in the art, or, alternatively, at least one of any type of rechargeable battery. Battery unit 20 voltage is preferably 12 volts DC, to control cost by using existing battery technology, but is selectable to match the voltage requirements of the motors 16 used. The structural member is commonly provided as a tubular column, typically formed of a metal such as steel. The invention is not limited by the shape or material of the structural member.

Conditioning equipment 26 is disposed between the photovoltaic cell array 24 and each battery unit 20, and connected to the photovoltaic cell array 24 via a power conditioner supply line 28. Between the conditioning equipment 26 and the battery unit 20, a battery recharge line 30 is disposed. The conditioning equipment 26 is known in the art and includes over-voltage protection, over-charging protection, and control of the charging rate. Battery monitoring equipment 32 is connected to the conditioning equipment 26 via a monitoring line 34. The battery monitoring equipment 32 is known in the art and includes battery voltage measurement, current measurement, battery charge indication, and/or indication of a failed photovoltaic cell array 24.

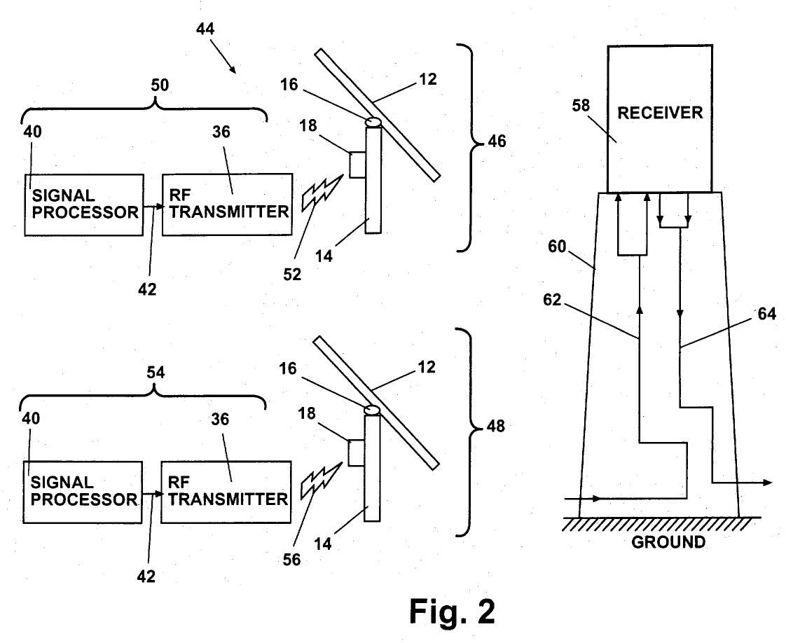

A radio frequency transmitter 36 is remotely positioned from each of the heliostats 19. The radio frequency transmitter 36 produces a radio frequency wireless signal 38. The radio frequency wireless signal 38 will be described in further detail with reference to FIG. 2. The frequency of the radio frequency wireless signal 38 is compatible with each of the radio frequency receivers 18. A signal processor 40 is provided to generate each of the radio frequency wireless signals 38 for transmission by the radio frequency transmitter 36. A signal transfer line 42 is provided between the signal processor 40 and the radio frequency transmitter 36. The signal processor 40 is connectable to other computing and data collection equipment, normally positioned at a central processing facility, (not shown), which store data on solar position based on time of day and/or time of year, heliostat global location, etc. This equipment and data are well known and will not be further discussed herein. It is anticipated that the signal processor 40 will generate an updated radio frequency wireless signal 38 at periodic intervals determined by an operator of the system. An exemplary periodic interval is approximately every thirty seconds.

Referring next to FIG. 2, a heliostat system 44 for another preferred embodiment of the present invention includes a first heliostat group 46 and a second heliostat group 48. Each of the first and second heliostat groups include at least two heliostats 19. The first heliostat group 46 also includes a local signal supply 50 which includes one of the signal processors 40 and one of the radio frequency transmitters 36. Similarly, the second heliostat group 48 also includes a local signal supply 54. The local signal supply 54 includes one of the signal processors 40 and one of the radio frequency transmitters 36. The local signal supply 50 transmits a first wireless signal 52 to the first heliostat group 46. The local signal supply 54 transmits a second wireless signal 56 to the second heliostat group 48. Each of the first wireless signal 52 and the second wireless signal 56 can further include individual unique frequencies or individual unique addresses on a single frequency for each of the reflectors 12 associated with the first heliostat group 46 and/or the second heliostat group 48, respectively.

FIG. 2 also shows a common solar receiver 58 disposed on a tower 60 as known in the art, for receiving the solar radiation reflected from each of the reflectors 12 of the heliostat system 44. The solar radiation received at the solar receiver 58 is commonly used to heat a heat transfer fluid provided in an inlet line 62 and discharged in a heated discharge line 64. The heated fluid (not shown) can thereafter be used to generate steam and further to generate electricity, or depending on the fluid type, directly used to generate electricity.

It should be obvious that the quantity of reflectors 12 used in each of the first heliostat group 46 and the second heliostat group 48 of the heliostat system 44 can vary and that the number of heliostat groups can vary. At least two reflectors 12 are used in each of the first heliostat group 46 and the second heliostat group 48, respectively. Each of the reflectors 12 provided in the first heliostat group 46 and the second heliostat group 48 are also commonly or individually locally connected to batteries; photovoltaic cell arrays; conditioning equipment; and battery monitoring equipment, similar to that shown in FIG. 1. This equipment is not shown in FIG. 2 for clarity. It should also be noted that each local signal supply 50 and local signal supply 54 can be located at any distance within radio frequency transmission range of the individual reflectors 12.

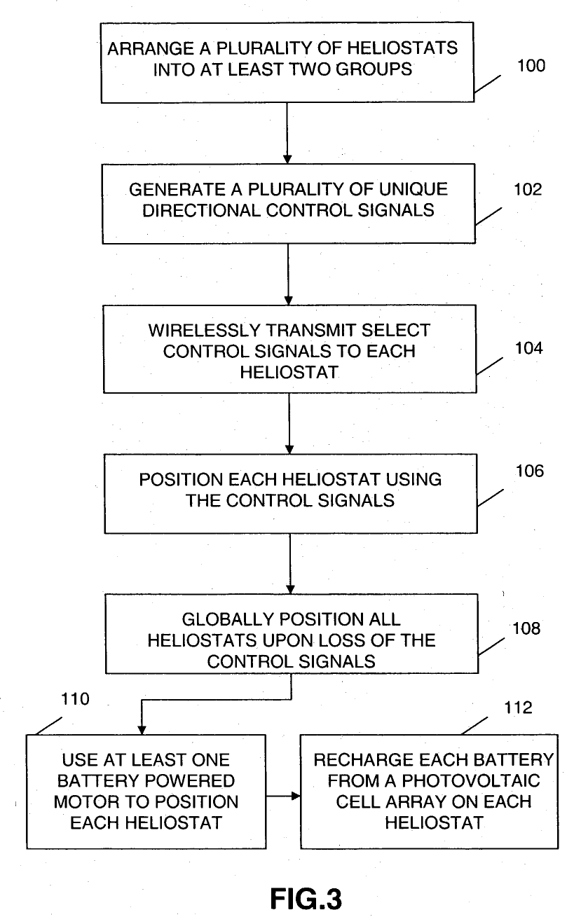

As best seen in FIG. 3, a method to operate a heliostat system of the present invention is described. In a first step 100, individual heliostats are arranged into at least two groups of heliostats. At step 102, a plurality of unique directional control signals is generated by at least one signal processor. In a following step 104, select ones of the directional control signals are wirelessly transmitted to each heliostat. In a positioning step 106, each heliostat is positioned using the received directional control signal. At step 108, all of the heliostats in a heliostat system are globally positioned to a fail-safe position upon loss of the control signals. In a further step 110, at least one battery powered motor is used to position each heliostat. In a final step 112, each battery unit powering each motor is recharged from a photovoltaic cell array disposed on each heliostat.

Referring finally to FIG. 4, an exemplary heliostat 120 includes a first reflector 122 and a second reflector 124, both supported by a structural member 126. The structural member 126 is preferably partially inserted in the ground for support. Optionally, the structural member 126 is connectably disposed to a support plate 128, which is anchored to and transfers heliostat loads to a ground surface. The first reflector 122 and the second reflector 124 are co-rotated by an azimuth motor 130 and an elevation motor 132. Both the azimuth motor 130 and the elevation motor 132 are supported from the structural member 126. The first reflector 122 and the second reflector 124 are driven by the azimuth motor 130 to rotate in the rotational direction “A” about the structural member 126 longitudinal axis “B”. Similarly, the first reflector 122 and the second reflector 124 are driven by the elevation motor 132 to rotate in the elevation rotation direction “C”. A solar receiver section 134 (shown in phantom), is located remote from heliostat 120, and is similar to the solar receiver 58 shown in FIG. 2. A radio frequency receiver 136 is shown mounted to the structural member 126. A battery unit 138 is connected to the receiver 136 by a battery power cable 140. The receiver is connected to both the azimuth motor 130 and the elevation motor 132 by a motor power cable 142. A photovoltaic cell array 144 is mounted in this embodiment to the first reflector 122. A power conditioner 146 is connected to the battery unit 138 by a power conditioning cable 148. A battery monitoring system 150 is also supported by the support plate 128 and connected to the battery unit 138 by a monitoring cable 152.

In operation, the position of the heliostat 120 is monitored by an encoder (not shown) as known, and the radio frequency control signal 135 is generated similar to first and second wireless signals 52 and 56 respectively, with new position data. The heliostat 120 receives the radio frequency control signal 135 at the radio frequency receiver 136. The radio frequency receiver closes a current flow path between the battery unit 138 and appropriate one(s) of the azimuth motor 130 and the elevation motor 132 co-rotate the first and second reflectors, 122 and 124. Either or both of the azimuth motor 130 and the elevation motor 132 can be energized. Individual frequencies or different addresses on the same frequency can be used for the radio frequency control signal 135 to initiate operation of the azimuth motor 130 and the elevation motor 132. When positioned by either or both the azimuth motor 130 and the elevation motor 132, light incident along the incident energy path “D” is reflected off both the first reflector 122 and the second reflector 124 along a reflected energy path “E” to the solar receiver section 134 (shown in phantom), which is similar to receiver 58 shown in FIG. 2. Light incident on the photovoltaic cell array 144 generates an electrical current which is conducted by a cable (not shown) to the battery unit 138, via the power conditioner 146, to recharge the battery unit 138.

A heliostat system of the present invention provides several advantages. By providing local battery power to each heliostat or several heliostats, the kilometers of cabling required to connect to the often several thousand heliostats is eliminated. By wirelessly signaling each heliostat, the processing and transmitting equipment can be located at any distance within radio frequency transmission range of the heliostats. The use of batteries to power the motors of each heliostat provides a low cost, simple system to maintain wherein batteries can be replaced when the individual battery unit fails to accept a recharge. By providing local photovoltaic cell arrays associated with one or several heliostats, the local batteries can be recharged. The use of photovoltaic cell arrays and batteries provides for autonomous operation of the heliostats. By grouping heliostats, the associated transmitter and processor equipment can be positioned local to each group to improve maintenance. Finally, by providing a fail-safe position for each heliostat, each heliostat will reposition to the fail-safe position upon loss of the wireless control signals, thereby reducing the potential to damage the solar receiver, the receiver tower, or the heliostats themselves.

The description of the invention is merely exemplary in nature and, thus, variations that do not depart from the gist of the invention are intended to be within the scope of the invention. Such variations are not to be regarded as a departure from the spirit and scope of the invention.

What is claimed is:

1. A remotely powered heliostat system, comprising:
a plurality of heliostats each including a reflector movably disposed on an associated structural member, each said reflector having at least one facet;
at least one motor disposed between each said reflector and said associated structural member;
said plurality of heliostats being further divisible into at least two groups of heliostats; and
each said heliostat further including a wireless receiver to operably receive a wireless heliostat positioning command for each said heliostat of each said group to remotely position each said heliostat.

2. The system of claim 1, comprising a battery unit connectably disposed to each said group of said heliostats to operatively provide a source of electrical power to each said group of said heliostats.

3. The system of claim 2, comprising at least one photovoltaic cell array disposed approximate to each said group of heliostats operatively providing a recharging current to said battery unit.

4. The system of claim 3, comprising an electrical conditioning system connectably disposed between said photovoltaic cell array and said battery unit.

5. The system of claim 4, comprising a battery monitoring system electrically connected to said electrical conditioning system.

6. The system of claim 1, comprising:
said heliostat positioning command being operable within a radio frequency range; and
an electrical connection disposed between said radio frequency receiver and said motor.

7. The system of claim 1, wherein each said heliostat further comprises a battery unit operatively providing a source of electrical power to said motor.

8. The system of claim 7, wherein each said heliostat further comprises a photovoltaic cell array operatively providing a recharging current to said battery unit.

9. The system of claim 1, wherein said at least one motor includes a reflector azimuth control motor and a reflector elevation control motor.

10. A power generation system, comprising:
a plurality of heliostats each having a reflector movably disposed on a structural member, said plurality of heliostats being operably divisible into at least two groups of heliostats;
at least one motor disposed between each said reflector and said structural member operably controlling an orientation of said reflector;
a transmitter uniquely associated with and in wireless communication with each said group, operable to wirelessly transmit a distinct set of heliostat group position signals to said heliostat group; and
a radio frequency receiver electrically connected to each said heliostat and in wireless communication with said transmitter, operable to receive said heliostat group position signals and direct an operation of said motor.

11. The system of claim 10, comprising:
a battery unit disposed approximate to each said heliostat, said battery unit electrically connectable to said motor; and
a photovoltaic cell array connectable to said battery unit to recharge said battery unit.

12. The system of claim 10, comprising at least one processor communicatively linked with said transmitter, said processor operably generating each said heliostat group position signal.

13. The system of claim 12, wherein each said heliostat group position signal comprises one of a unique frequency range, and a unique address on a single frequency.

14. The system of claim 10, comprising a plurality of heliostat orientations each operably determined by said processor.

15. The system of claim 10, comprising a fail-safe orientation signal for each said heliostat, pre-programmable into said receiver and operably positioning each said heliostat upon loss of said group position signal.

16. The system of claim 10, wherein said at least one processor comprises a plurality of individual processors each positionable adjacent to one of said group of heliostats.

17. A method to control a plurality of heliostats, comprising the steps of:
arranging a plurality of heliostats into at least two groups;
generating a plurality of unique directional control signals;
wirelessly transmitting select ones of said directional control signals to one of said groups;
using said select ones of said directional control signals to position each said heliostat of said one group; and
globally positioning said plurality of heliostats in a fail-safe position upon loss of said directional control signals.

18. The method of claim 17, comprising selecting one of a unique frequency and a unique address on a single frequency for each of said directional control signals.

19. The method of claim 17, comprising operating at least one electric motor to locally position each said heliostat.

20. The method of claim 19, comprising powering each said electric motor with a battery unit.

21. The method of claim 20, comprising recharging said battery unit from a photovoltaic cell array.

22. The method of claim 17, comprising:
calculating an orientation of each said heliostat relative to a solar position; and
adjusting an orientation of each said heliostat to reflect solar radiation incident thereon.

23. The method of claim 17, comprising disposing a radio frequency receiver on each said heliostat to receive said directional control signal.
